(19) United States
(12) Patent Application Publication
(10) Pub. No.: US 2019/0348556 A1
(43) Pub. Date: Nov. 14, 2019

(54) LAMINATING DEVICE AND LAMINATING METHOD

(71) Applicant: Beijing Hanergy Solar Power Investment Co., Ltd., Beijing (CN)

(72) Inventors: Dongchun CHEN, Beijing (CN); Xin ZHANG, Beijing (CN); Dawei Liu, Beijing (CN)

(21) Appl. No.: 16/105,228

(22) Filed: Aug. 20, 2018

(30) Foreign Application Priority Data
May 8, 2018 (CN) 201810432348.6
May 8, 2018 (CN) 201820682054.4

(51) Int. Cl. H01L 31/048; B32B 37/10; H01L 31/0445; H01L 31/18

(52) U.S. Cl. CPC H01L 31/0488; B32B 37/1018; B32B 2457/12; H01L 31/1876; H01L 31/0445

(57) ABSTRACT

The present disclosure provides a laminating device including a case body, a heating system, a vacuuming system, and a hot air circulation system, a member to be laminated being placed inside the case body, the vacuuming system being configured for vacuuming the member to be laminated inside the case body, the heating system being configured for heating the member to be laminated inside the case body, and the hot air circulation system being configured for driving air in the case body to flow during heating by the heating system. Accordingly, the present disclosure further provides a laminating method.

### CROSS-REFERENCE TO RELATED APPLICATION

This application claims the priority of Chinese Application Nos. 201810432348.6 and 201820682054.4 filed on May 8, 2018, which are hereby incorporated by reference in its entirety.

### TECHNICAL FIELD

The present disclosure relates to but is not limited to a solar energy power generation technology, and particularly relates to but is not limited to a laminating device and a laminating method.

### BACKGROUND OF THE INVENTION

With increasing environmental protection requirements and development in photovoltaic technologies, thin film assemblies will become the development trend of future photovoltaic products.

Double or triple-glass assemblies among the thin film assemblies are required to undergo heating and vacuuming during processing to ensure that the assemblies are laminated to be an integral body. However, conventional equipment used in a laminated processing of an above-mentioned assembly, such as laminators and laminated glass roller presses, has various defects, such as air bubbles occurring inside the assembly during the lamination, and has high energy consumption; some air is dissolved in an internal adhesive sheet of the assembly because it is not discharged in time so that air is easily separated out during operation of the assembly, leading to air bubbles inside the assembly, affecting power generation efficiency and life of the assembly.

### SUMMARY

The following is a summary of the subject matter described in detail in the present disclosure. This summary is not intended to limit the scope of the claims.

According to an aspect of the present disclosure, there is provided a laminating device including a case body in which a member to be laminated is placed, a heating system configured for heating the member to be laminated, a vacuuming system configured for vacuuming the member to be laminated, and a hot air circulation system configured for driving air in the case body to flow during a heating process.

According to an implementation of the present disclosure, the air in the case body may flow in a circulating manner.

According to an implementation of the present disclosure, the laminating device is capable of vacuuming the member to be laminated by the vacuuming system and heating the member to be laminated by the heating system. Meanwhile, due to including the hot air circulation system, air in the case body may be effectively driven to flow during heating by the heating system, thus ensuring temperature uniformity of the air in the case body, preventing air bubbles from occurring in the member to be laminated during the laminating, and therefore improving quality of a laminated assembly.

According to an implementation of the present disclosure, the laminating device further comprises a control system connected to the heating system and the vacuuming system, a preset vacuum pressure value and a preset temperature curve are stored in the control system, the vacuuming system is configured for vacuuming the member to be laminated inside the case body under control of the control system till a vacuum degree of the member to be laminated reaches and maintains at the preset value, and the heating system is configured for heating the member to be laminated inside the case body according to the preset temperature curve under control of the control system.

According to an implementation of the present disclosure, the hot air circulation system comprises at least one circulation fan and at least one circulation duct, each of circulation duct matches with a corresponding one of the at least one circulation fan, the circulation fan is disposed on the case body, and the circulation duct is disposed inside the case body and extends along an inner wall of the case body.

According to an implementation of the present disclosure, circulating air from an air inlet of the circulation duct flows from top to bottom along the circulation duct, and, after flowing out from an air outlet of the circulation duct, passes the member to be laminated upwardly from a bottom of the case body, and then returns to the air inlet of the circulation duct.

According to an implementation of the present disclosure, a power of each circulation fan can be ranged from 1.5 to 2.5 kw, and a blast capacity thereof can be in a range of 3000-4000 m³/h.

According to an implementation of the present disclosure, a hole structure is provided in the case body aligned with the air outlet of the circulation duct.

According to an implementation of the present disclosure, the heating system comprises a heater and at least one heating pipe, and the heater is configured for supplying electricity to the heating pipe.

According to an implementation of the present disclosure, the heater is disposed outside the case body, and the heating pipe is disposed inside the circulation duct.

According to an implementation of the present disclosure, the laminating device further comprises an exhaust cooling system configured for cooling the member to be laminated after the heating process.

According to an implementation of the present disclosure, the exhaust cooling system comprises at least one cooling fan disposed on the case body.

According to an implementation of the present disclosure, the vacuuming system comprises a vacuum pump disposed outside the case body and at least one vacuuming duct disposed inside the case body, each vacuuming duct being provided with at least one vacuuming nozzle.

According to an implementation of the present disclosure, the member to be laminated is enveloped with a rubber ring at a periphery thereof, and the vacuuming nozzle is disposed between the member to be laminated and the rubber ring.

According to an implementation of the present disclosure, the vacuuming nozzle has a conic threaded structure.

According to an implementation of the present disclosure, a movable rack configured for holding the member to be laminated is provided inside the case body.

According to an implementation of the present disclosure, the member to be laminated is a double or triple glass thin film photovoltaic assembly.

According to another aspect of the present disclosure, there is provided a laminating method, comprising: vacuuming a member to be laminated; and heating the member to be laminated, and driving air around the member to be laminated to flow during the heating process.

According to an implementation of the present disclosure, the air around the member to be laminated may be driven to flow circularly. Specifically, circulating air from an air inlet of the circulation duct is driven to flow from top to bottom along the circulation duct, then flow out from an air outlet of the circulation duct, and subsequently pass the member to be laminated upwardly from a bottom of the case body, and then return to the air inlet of the circulation duct.

In the laminating method of the present disclosure, the member to be laminated is vacuumed and heated, while during heating the member to be laminated, the air around the member to be laminated is driven to flow, thus ensuring a uniform air temperature around the member to be laminated, preventing air bubbles from occurring in the member to be laminated during the laminating, and improving quality of a laminated assembly.

According to an implementation of the present disclosure, the laminating method further comprises cooling the member to be laminated after the heating process.

According to an implementation of the present disclosure, in the laminating method, vacuuming the member to be laminated comprises: vacuuming the member to be laminated for a first preset time period, and maintaining a vacuum degree of the member to be laminated at a preset vacuum pressure value till the laminating is finished; and heating the member to be laminated comprises: heating the member to be laminated to a first temperature value at a first heating rate, and then heating the member to be laminated to a second temperature value at a second heating rate, the first temperature value being lower than the second temperature value and the first heating rate being higher than the second heating rate.

According to an implementation of the present disclosure, the first preset time period may be in a range of 10 to 15 min; the first heating rate may be in a range of 5° C./min to 10° C./min; the first temperature value may be in a range of 70 to 80° C.; the second heating rate may be in a range of 4° C./min to 8° C./min; and the second temperature value may be in a range of 120 to 130° C. The skilled in the art will understand that the above ranges are merely illustrative, and may be adjusted or changed according to the specific process requirements of the member to be laminated.

According to an implementation of the present disclosure, the laminating method further comprises: maintaining the member to be laminated at a constant temperature and a constant pressure for a second preset time period so that layers in the member to be laminated are bonded into an integral laminated member, the second preset time period being longer than the first preset time period; and cooling the laminated member to a third temperature value at a first cooling rate, and then cooling the laminated member to a fourth temperature value at a second cooling rate, the third temperature value being higher than the fourth temperature value, and the first cooling rate being lower than the second cooling rate.

According to an implementation of the present disclosure, the second preset time period may be in a range of 30 to 50 min; the first cooling rate may be in a range of 5 to 6° C./min; the third temperature value may be in a range of 70 to 80° C.; the second cooling rate may be in a range of 7 to 8° C./min; and the fourth temperature value may be in a range of 30 to 40° C. The skilled in the art will understand that the above ranges are merely illustrative, and may be adjusted or changed according to the specific process requirements of the member to be laminated.

According to the present disclosure, the laminating method further comprises: enveloping a periphery of the member to be laminated with a rubber ring and checking whether air is leaked from the rubber ring, prior to vacuuming the member to be laminated.

Other aspects will be apparent after the drawings and the detailed description are read and understood.

### BRIEF DESCRIPTION OF THE FIGURES

FIG. 1 is a front view of a laminating device according to Embodiment 1 of the present disclosure;

FIG. 2 is a side view of the laminating device according to Embodiment 1 of the present disclosure;

FIG. 3 is a schematic view showing an internal structure of the laminating device according to Embodiment 1 of the present disclosure;

FIG. 4 is another schematic view showing the internal structure of the laminating device according to Embodiment 1 of the present disclosure;

FIG. 5 is a partial enlarged view at a location A in FIG. 4;

FIG. 6 is a structural schematic view of a vacuuming nozzle in FIG. 5;

FIG. 7 is a partial enlarged view at a location B in FIG. 4;

FIG. 8 is a schematic view of a member to be laminated mounted with a rubber ring at a periphery thereof;

FIG. 9 is a flowchart of a laminating method according to Embodiment 2 of the present disclosure;

FIG. 10 is a flowchart of another laminating method according to Embodiment 2 of the present disclosure; and

FIG. 11 is a schematic view showing a preset temperature curve stored in a control system of the laminating device of the present disclosure.

### DETAILED DESCRIPTION

To achieve a better understanding of technical solutions of the present disclosure for the skilled in the art, a laminating device and a laminating method provided in the present disclosure will be described in detail below in connection with the accompanying drawings.

### Embodiment 1

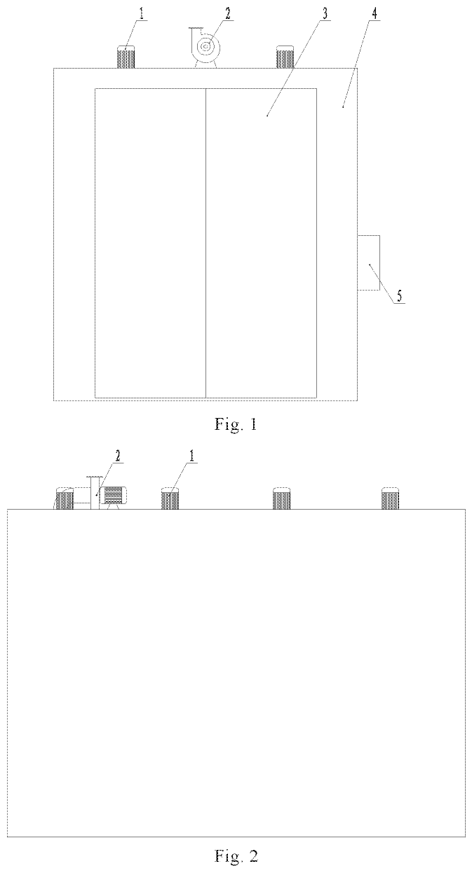

As shown in FIGS. 1 to 4, this embodiment provides a laminating device including an enclosable case body 4, a heating system 100, a vacuuming system 200 and a hot air circulation system 300. A member to be laminated 10 is placed in the case body 4, the vacuuming system 200 is configured for vacuuming the member to be laminated 10 inside the case body 4, the heating system 100 is configured for heating the member to be laminated 10 inside the case body 4, and the hot air circulation system 300 is configured for driving air in the case body 4 to flow during a heating process by the heating system 100. The member to be laminated 10 may be any two-layer or more than two-layer structure that is required to be laminated, such as a double or triple glass thin film photovoltaic assembly.

In the present embodiment, the member to be laminated 10 may be vacuumed by the vacuuming system 200 and heated by the heating system 100. Meanwhile, with the hot air circulation system 300, air in the case body may be effectively driven to flow during a heating process by the heating system 100, thus ensuring temperature uniformity of the air in the case body, preventing air bubbles from occurring in the member to be laminated 10 during the laminating, and improving quality of a laminated assembly.

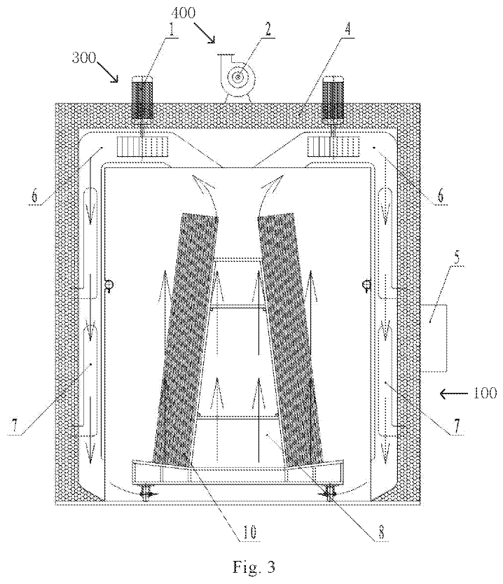

As shown in FIGS. 1 and 3, the laminating device further includes a control system 5 connected to the heating system 100 and the vacuuming system 200. A preset vacuum pressure value and a preset temperature curve are stored in the control system 5 so as to control the whole processing. Meanwhile, the control system 5 may also store other process parameters so as to directly call up them when is needed in use. The vacuuming system 200 is configured for vacuuming the member to be laminated 10 inside the case body 4 under control of the control system 5 till a vacuum degree of the member to be laminated 10 reaches and maintains at the preset vacuum pressure value; the heating system 100 is configured for heating the member to be laminated 10 inside the case body 4 according to the preset temperature curve under control of the control system 5 so that layers in the member to be laminated 10 are bonded into an integral laminated member. The preset vacuum pressure value is in a range of −100 to −200 kpa. For example, the preset vacuum pressure value may be about −150 kpa.

FIG. 11 is a schematic view showing a preset temperature curve stored in the control system of the laminating device according to an embodiment of the present disclosure. As shown in FIG. 11, after the air in the case body reaches the preset vacuum pressure value at a time t1, the member to be laminated is first heated from an approximate room temperature to a first temperature value W1 at a first heating rate during a time period t1 to t2, and then heated to a second temperature value W2 at a second heating rate during a time period t2 to t3. Then, the member to be laminated is maintained at a constant temperature and a constant pressure during a time period t3 to t4 so that layers in the member to be laminated are bonded into an integral laminated member. When cooling the member to be laminated after the heating process, the member to be laminated is cooled to a third temperature value W3 at a first cooling rate during a time period t4 to t5 to prevent air from entering and maintain the bonding effect. Then, the member to be laminated is cooled to a fourth temperature value W4 at a second cooling rate during a time period t5 to t6 to save time and improve efficiency.

Specific values of times and temperatures in the preset temperature curve may be determined according to the specific process requirements of the member to be laminated. In the present embodiment, specific values of times and temperatures in the preset temperature curve may refer to the process requirements in the following Embodiment 2.

In the present embodiment, with the control system 5, the vacuuming system 200 and the heating system 100 may be operated according to a preset program, thus increasing degree of automation and avoiding maloperation.

As shown in FIGS. 1 to 3, the hot air circulation system 300 includes at least one circulation fan 1 and a circulation duct 6 matching with each circulation fan 1, the circulation fan 1 is disposed on the case body 4, and the circulation duct 6 is disposed inside the case body 4 and extends along an inner wall of the case body 4.

In the present embodiment, the circulation duct 6 extends along the inner wall of the case body 4 and enables the air in the case body 4 to flow circularly, thus ensuring better uniformity of the air temperature in the case body 4.

FIGS. 1 to 3 show eight circulation fans 1 disposed on a top of the case body 4 in two rows and four columns, and each of the circulation fans 1 matches with a circulation duct 6. Each circulation duct 6 extends from an inner top (an air inlet) of the case body 4 to a side wall of the case body, passes an inner side wall of the case body 4 from top to bottom till it approaches an inner bottom (an air outlet) of the case body 4. However, the present disclosure is not limited thereto; the skilled in the art may set the number and the positions of the circulation fans 1 and the position of each circulation duct 6 according to actual situations.

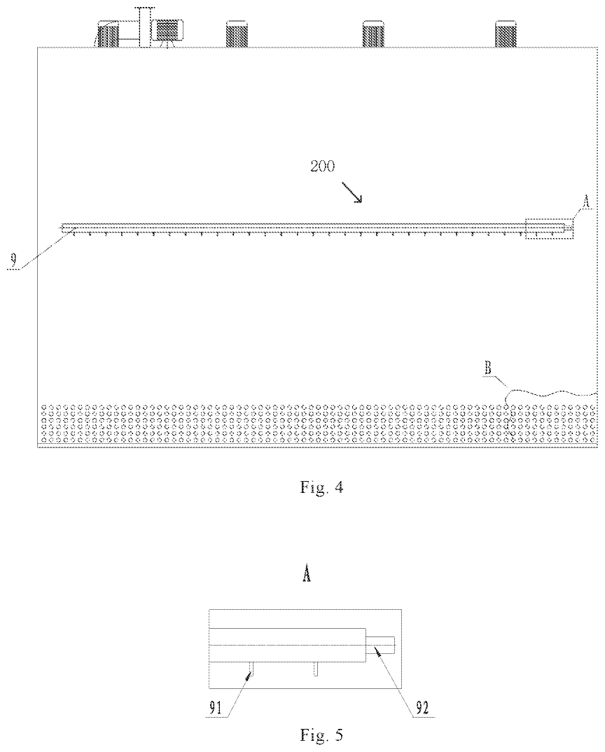

In an embodiment, as shown in FIGS. 4 and 7, a hole structure, such as a circular hole structure arranged in a matrix form, is provided in the case body 4 at a position aligned to the air outlet of each circulation duct 6 so as to realize better uniformity of the air flow and temperature in the case body. FIG. 4 shows that a position of the case body 4 corresponding to the air outlet of each circulation duct 6 is a bottom of opposite side walls of the case body 4, that is, a bottom of a left side wall and a right side wall of the case body 4 as shown in FIG. 3, and the hole structure is provided throughout the bottom of the opposite side walls of the case body.

As shown in FIG. 3, in an embodiment, circulating air from the air inlet of the circulation duct 6 flows from top to bottom along the circulation duct 6 (i.e., the inner side wall of the case body 4), and after flowing out from the air outlet of the circulation duct 6, passes the member to be laminated 10 upwardly from a bottom of the case body 4 (a bottom of a movable rack 8 to be described below), and then returns to the air inlet of the circulation duct 6. It should be noted that the circulation manner of the circulating air is not limited thereto, but the air may be circulated in an opposite direction. In this case, positions of the air inlet and the air outlet of the circulation duct 6 are exchangeable.

In order to achieve the air circulation effect desired by the present disclosure, the circulation fan 1 used in the hot air circulation system 300 has a power ranging from 1.5 to 2.5 kW and a blast capacity ranged from 3000 to 4000 m³/h. The power and the blast capacity are directed to single fan and may be adjusted according to a volume of the case body as well as the number of fans.

As shown in FIG. 3, the heating system 100 includes a heater and at least one heating pipe 7. The heater is configured for supplying power to the heating pipe 7 which converts electrical energy into thermal energy to heat the air in the case body 4, thereby providing the heat energy for melting an adhesive (e.g., an adhesive sheet) among layers of the member to be laminated 10 and bonding all layers into an integral body.

Specifically, the heater is disposed outside the case body 4, while the heating pipe 7 is disposed inside the circulation duct 6 to heat the air in the circulation duct 6. In an embodiment, at least one heating pipe 6 is provided inside the circulation duct 6 matching with each circulation fan 1.

In the present embodiment, the laminating device further includes an exhaust cooling system 400 configured for cooling the member to be laminated 10 after the heating process so as to quickly reduce a temperature of the member to be laminated 10 inside the case body, thus saving cooling time and improving production efficiency.

Specifically, as shown in FIGS. 1-3, the exhaust cooling system 400 comprises at least one cooling fan 2 disposed on the case body 4. FIGS. 1-3 show that only one cooling fan 2 is provided on the top of the case body 4, but the present disclosure is not limited thereto; the skilled in the art may set the number and the position of the cooling fan according to actual situations.

As shown in FIGS. 4 and 5, the vacuuming system 200 includes a vacuum pump disposed outside the case body 4 and at least one vacuuming duct 9 disposed inside the case body 4. Each vacuuming duct 9 is provided with at least one vacuuming nozzle 91. When each vacuuming duct 9 is provided with a plurality of vacuuming nozzles 91, each of the vacuuming nozzles 91 may be arranged along a lengthwise direction of the vacuuming duct 9. In addition, an end of each vacuuming duct 9 may be provided with an extendable interface 92 for connecting other vacuuming ducts.

In practical applications, as shown in FIG. 8, the member to be laminated 10 is enveloped with a rubber ring 11 at a periphery thereof so as to wrap up all sides of the member to be laminated 10 and prevent air leakage. Further, a vacuuming passage 12 is formed between a side surface of the member to be laminated 10 and an inner side of the rubber ring 11. The vacuuming nozzle 91 is connected to the rubber ring 11, and inserted and fixed between the inner side of the rubber ring 11 and the side surface of the member to be laminated 10. When the vacuuming system works, the air is separated out from the vacuuming passage 12 and the member to be laminated due to heating is evacuated till a vacuum degree of the member to be laminated reaches and maintains at the preset vacuum pressure value.

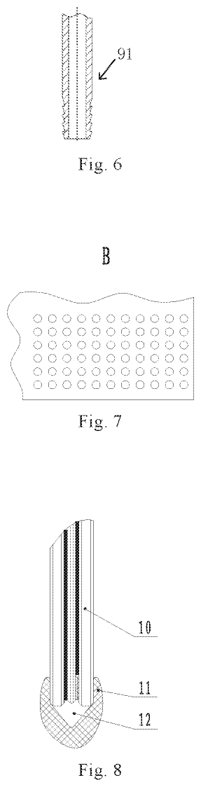

In an embodiment, as shown in FIG. 6, the vacuuming nozzle 91 has a conic threaded structure to facilitate mounting on the rubber ring 11, thus improving the production efficiency.

As shown in FIG. 3, a movable glass rack 8 configured for holding the member to be laminated 10 is provided inside the case body 4. A spacer is provided on the glass rack 8 so that after the member to be laminated 10 is placed on the glass rack 8, a distance in range of 10 to 20 mm is left between every two neighboring members to be laminated 10 to facilitate air circulation.

The movable glass rack 8 may be an A-type glass rack or a square stop lever glass rack. In an embodiment, a A-type glass rack is used.

In the present embodiment, the case body 4 may be made of material selected from a heat insulating material, a section material, and the like, while ensuring that an interior of the case body is enclosed. One or two double leaf doors (i.e., a case body door 3 in FIG. 1) may be opened on a side surface of the case body. The double leaf door is wrapped with a sealing silicone ring at a periphery thereof to prevent heat energy loss and reduce energy consumption.

To summarize, by providing the circulation duct 6 and providing the hole structure at the position of the case body 4 corresponding to the circulation duct 6, the laminating device of the present embodiment may realize uniformity of the air flow and the temperature in the case body 4; by reserving the extendable interface 92 for the vacuuming duct, a length of the vacuuming duct and the number of the vacuuming nozzle 91 may be extended, thus improving work efficiency; by designing the structure of the vacuuming nozzle 91, a connection to the member to be laminated 10 is facilitated, thus improving the work efficiency; processing of a standard, profiled or arc-shaped assembly may be performed; the temperature and the air flow in the case body are more uniform and the energy consumption is reduced.

### Embodiment 2

This embodiment provides a laminating method which is applicable to not only the laminating device in Embodiment 1 but also laminating devices of other types.

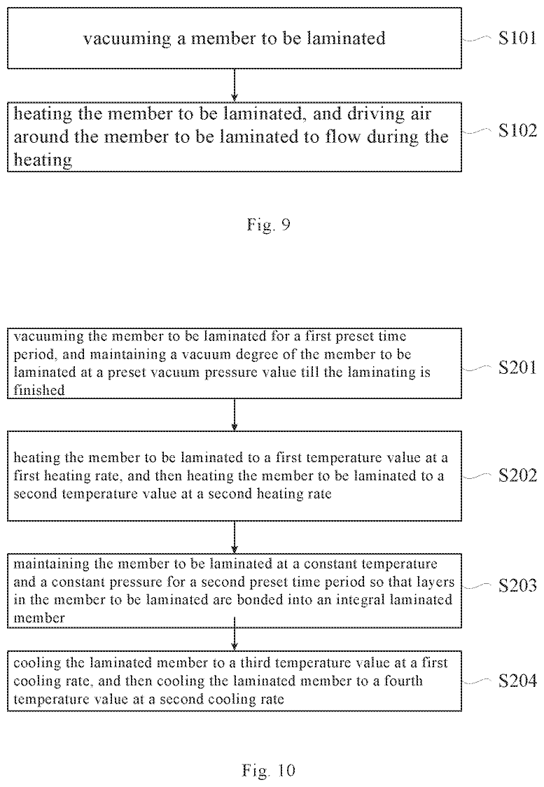

As shown in FIG. 9, as a specific implementation of the present embodiment, the laminating method includes the following steps S101 and S102.

S101, vacuuming a member to be laminated; and

S102, heating the member to be laminated, and driving air around the member to be laminated to flow during the heating.

In the laminating method of the present embodiment, the member to be laminated is vacuumed and heated, while during heating the member to be laminated, the air around the member to be laminated is driven to flow, thus ensuring temperature uniformity of the air around the member to be laminated, preventing air bubbles from occurring in the member to be laminated during the laminating, and improving quality of a laminated assembly.

In an embodiment, the laminating method further comprises:

cooling the member to be laminated after it has been heated.

In the present embodiment, by cooling the member to be laminated after the heating process, a temperature inside the case body may be quickly cooled down, thus saving cooling time and improving production efficiency.

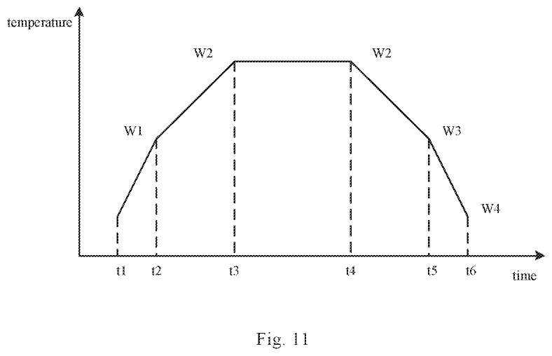

As shown in FIG. 10, as another specific embodiment of the present embodiment, the laminating method includes the following steps S201 to S204.

S201, during vacuuming the member to be laminated, vacuuming the member to be laminated for a first preset time period, and maintaining a vacuum degree of the member to be laminated at a preset vacuum pressure value till the laminating is finished;

S202, during heating the member to be laminated, heating the member to be laminated to a first temperature value at a first heating rate, and then heating the member to be laminated to a second temperature value at a second heating rate; wherein the first temperature value is lower than the second temperature value and the first heating rate is higher than the second heating rate;

S203, maintaining the member to be laminated at a constant temperature and a constant pressure for a second preset time period so that layers in the member to be laminated are bonded into an integral laminated member; wherein the second preset time period is longer than the first preset time period so as to ensure sufficient flowing of the air around the member to be laminated and uniformity of air temperature; and

S204, cooling the laminated member to a third temperature value at a first cooling rate, and then cooling the laminated member to a fourth temperature value at a second cooling rate; wherein the third temperature value is higher than the fourth temperature value, and the first cooling rate is lower than the second cooling rate.

As described above, referring to FIG. 11, after the air in the case body reaches the preset vacuum pressure value, the member to be laminated is first heated to the first temperature value W1 at the first heating rate, and then heated to the second temperature value W2 at the second heating rate. On one hand, the adhesive sheet within the member to be laminated may reach a melting temperature as soon as possible, and on the other hand, the adhesive sheet reaching the melting temperature may continue to be heated sufficiently and uniformly to prevent air from entering and facilitate bonding. Based on the same consideration, when cooling the member to be laminated after the heating process, the member to be laminated is first cooled to a third temperature value W3 at a first cooling rate to prevent air from entering and maintain the bonding effect, and then cooled to a fourth temperature value W4 at a second cooling rate to save time and improve efficiency.

Depending on the specific process requirements of the member to be laminated, for example, the preset vacuum pressure value is about −150 kPa; the first preset time period may be in a range of 10 to 15 min; the first heating rate may be in a range of 5° C./min to 10° C./min, for example, the first heating rate is 5° C./min; the first temperature value is in a range of 70 to 80° C.; the second heating rate may be in a range of 4° C./min to 8° C./min, for example, the second heating rate is 4° C./min; the second temperature value is in a range of 120 to 130° C.; the second preset time period is in a range of 30 to 50 min; the first cooling rate is in a range of 5 to 6° C./min; the third temperature value is in a range of 70 to 80° C.; the second cooling rate is in a range of 7 to 8° C./min; and the fourth temperature value is in a range of 30 to 40° C. It should be noted that the range of the first temperature value may not be exactly the same as, but only partially overlap, the range of the third temperature value.

It can be noted that steps S201 to S204 are to heat and vacuum the member to be laminated according to a preset program.

In addition, if the laminating method is applied to the laminating device described in Embodiment 1, the following preparatory works are desired to be included before step S201:

enveloping a periphery of the member to be laminated with a rubber ring (it is required to check whether the rubber ring is damaged) so as to wrap up all sides of the member to be laminated and prevent air leakage;

opening the case body door and placing the member to be laminated on the movable rack;

connecting the vacuuming nozzle to the rubber ring enveloping the periphery of the member to be laminated, turning on the vacuum pump, and checking whether air is leaked from the rubber ring; and

closing the case body door, initiating the laminating device, and performing the heating and the vacuuming according to the preset program as shown in steps S201 to S204.

When step S204 is finished, the case body door may be opened and the finished laminated member may be taken out.

To summarize, in order to solve the technical problems existing in the conventional equipment used in the production and processing of an assembly, the present disclosure provides a laminating device and a laminating method which can be used for processing a standard, profiled or arc-shaped double/triple glass thin film photovoltaic assembly with better internal temperature uniformity, and can also reduce energy consumption and improve product lamination yield.

It should be understood that the above embodiments are merely exemplary embodiments for the purpose of illustrating the principle of the present disclosure, and the present disclosure is not limited thereto. Various modifications and improvements can be made by a person having ordinary skill in the art without departing from the spirit and essence of the present disclosure. Accordingly, all of the modifications and improvements also fall into the protection scope of the present disclosure.

### LIST OF REFERENCE SIGNS

1—circulation fan; 2—cooling fan; 3—case body door; 4—case body; 5—control system; 6—circulation duct; 7—heating pipe; 8—movable glass rack; 9—vacuuming duct; 91—vacuuming nozzle; 92—extendable interface; 10—member to be laminated; 11—rubber ring; 12—vacuuming passage; 100—heating system; 200—vacuuming system; 300—hot air circulation system; 400—exhaust cooling system.

What is claimed is:

1. A laminating device comprising a case body in which a member to be laminated is placed, a heating system configured for heating the member to be laminated inside the case body, a vacuuming system configured for vacuuming the member to be laminated inside the case body, and a hot air circulation system configured for driving air in the case body to flow during heating by the heating system.

2. The laminating device according to claim 1, wherein the laminating device further comprises a control system connected to the heating system and the vacuuming system, a preset vacuum pressure value and a preset temperature curve are stored in the control system, the vacuuming system is configured for vacuuming the member to be laminated inside the case body under control of the control system till a vacuum degree of the member to be laminated reaches and maintains at the preset vacuum pressure value, and the heating system is configured for heating the member to be laminated inside the case body according to the preset temperature curve under control of the control system.

3. The laminating device according to claim 1, wherein the hot air circulation system comprises at least one circulation fan and at least one circulation duct, each of circulation duct matches with a corresponding one of the at least one circulation fan, the circulation fan is disposed on the case body, and the circulation duct is disposed inside the case body and extends along an inner wall of the case body.

4. The laminating device according to claim 3, wherein circulating air from an air inlet of the circulation duct flows from top to bottom along the circulation duct, and, after flowing out of an air outlet of the circulation duct, passes the member to be laminated upwardly from a bottom of the case body, and then returns to the air inlet of the circulation duct.

5. The laminating device according to claim 3, wherein a hole structure is provided in the case body at a position corresponding to the air outlet of the circulation duct.

6. The laminating device according to claim 3, characterized in that the heating system comprises a heater and at least one heating pipe, and the heater is configured for supplying electricity to the heating pipe.

7. The laminating device according to claim 6, characterized in that the heater is disposed outside the case body, and the heating pipe is disposed inside the circulation duct.

8. The laminating device according to claim 1, wherein the laminating device further comprises an exhaust cooling system configured for cooling the member to be laminated after the heating process.

9. The laminating device according to claim 8, wherein the exhaust cooling system comprises at least one cooling fan disposed on the case body.

10. The laminating device according to claim 1, wherein the vacuuming system comprises a vacuum pump disposed outside the case body and at least one vacuuming duct disposed inside the case body, each vacuuming duct being provided with at least one vacuuming nozzle.

11. The laminating device according to claim 10, wherein the member to be laminated is enveloped with a rubber ring at a periphery thereof, and the vacuuming nozzle is inserted between the member to be laminated and the rubber ring.

12. The laminating device according to claim 1, wherein a movable rack configured for holding the member to be laminated is provided inside the case body.

13. The laminating device according to claim 1, wherein the member to be laminated is a double or triple glass thin film photovoltaic assembly.

14. A laminating method, comprising:
vacuuming a member to be laminated; and
heating the member to be laminated, and driving air around the member to be laminated to flow during the heating.

15. The laminating method according to claim 14, wherein the laminating method further comprises:
cooling the member to be laminated after finishing heating the member to be laminated.

16. The laminating method according to claim 14, wherein vacuuming the member to be laminated comprises:
vacuuming the member to be laminated for a first preset time period, and maintaining a vacuum degree of the member to be laminated at a preset vacuum pressure value till the laminating is finished; and
heating the member to be laminated comprises:
heating the member to be laminated to a first temperature value at a first heating rate, and then heating the member to be laminated to a second temperature value at a second heating rate, the first temperature value being lower than the second temperature value and the first heating rate being higher than the second heating rate.

17. The laminating method according to claim 16, further comprising:
maintaining the member to be laminated at a constant temperature and a constant pressure for a second preset time period so that layers in the member to be laminated are bonded into an integral laminated member, the second preset time period being longer than the first preset time period; and
cooling the laminated member to a third temperature value at a first cooling rate, and then cooling the laminated member to a fourth temperature value at a second cooling rate, the third temperature value being higher than the fourth temperature value, and the first cooling rate being lower than the second cooling rate.

18. The laminating method according to claim 14, the laminating method further comprises:
enveloping a periphery of the member to be laminated with a rubber ring; and checking whether air is leaked from the rubber ring before vacuuming the member to be laminated.
